(19) United States
(12) Patent Application Publication
(10) Pub. No.: US 2012/0214281 A1
(43) Pub. Date: Aug. 23, 2012

(54) METHOD FOR MANUFACTURING SEMICONDUCTOR DEVICE

(75) Inventors: Shigeki TOMITA, Ishikawa-ken (JP); Hideki OKUMURA, Kanagawa-ken (JP)

(73) Assignee: Kabushiki Kaisha Toshiba, Tokyo (JP)

(21) Appl. No.: 13/401,667

(22) Filed: Feb. 21, 2012

(30) Foreign Application Priority Data
Feb. 23, 2011 (JP) 2011-037421

(51) Int. Cl. H01L 21/331

(52) U.S. Cl. 438/138; 257/E21.384

(57) ABSTRACT

According to one embodiment, a method for manufacturing a semiconductor device includes forming a mask layer containing silicon nitride on a semiconductor layer. The method includes forming a side wall film on a side wall of the mask layer. The method includes etching the semiconductor layer using the mask layer and the side wall film to form a gate trench. The method includes forming a gate electrode in the gate trench. The method includes removing the side wall film and forming a base region and a source region in the semiconductor layer using the mask layer. The method includes forming an interlayer film covering the semiconductor layer, the gate electrode and the mask layer, and containing silicon oxide. The method includes forming a contact trench, by using the interlayer film as a mask, in a portion of the semiconductor layer under a portion where the mask layer is removed.

### CROSS-REFERENCE TO RELATED APPLICATION

This application is based upon and claims the benefit of priority from Japanese Patent Application No. 2011-037421, filed on Feb. 23, 2011; the entire contents of which are incorporated herein by reference.

### FIELD

Embodiments described herein relate generally to a method for manufacturing a semiconductor device.

### BACKGROUND

The structure of a trench gate and a trench contact is used in, for example, power devices. By narrowing the pitch between trench gates (cell pitch), the channel density can be improved and a low ON resistance can be achieved. However, downsizing to a level of not more than the present cell pitch is becoming difficult in terms of the alignment accuracy of the trench contact to the trench gate in lithography.

### BRIEF DESCRIPTION OF THE DRAWINGS

FIG. 1 is a schematic cross-sectional view of a semiconductor device of an embodiment;

FIGS. 2A to 5C are schematic views showing a method for manufacturing the semiconductor device of the embodiment; and

FIGS. 6A to 6C are schematic views showing another method for manufacturing the semiconductor device of the embodiment.

### DETAILED DESCRIPTION

According to one embodiment, a method for manufacturing a semiconductor device is disclosed. The method can include forming a mask layer containing silicon nitride on a semiconductor layer containing silicon. The method can include forming a side wall film on a side wall of the mask layer. The method can include etching the semiconductor layer using the mask layer and the side wall film as a mask to form a gate trench in the semiconductor layer. The method can include forming a gate electrode in the gate trench via a gate insulating film. The method can include removing the side wall film and forming a base region and a source region in the semiconductor layer using the mask layer as a mask. The method can include forming an interlayer film covering the semiconductor layer, the gate electrode and the mask layer, and containing silicon oxide.

The method can include removing the mask layer selectively. In addition, the method can include forming a contact trench, by using the interlayer film as a mask, in a portion of the semiconductor layer under a portion where the mask layer is removed.

Hereinbelow, embodiments are described with reference to the drawings. In the drawings, identical components are marked with the same reference numerals.

A semiconductor device of an embodiment is a vertical device in which a current path is formed in the vertical direction connecting a first main electrode provided on one major surface side in the thickness direction of a semiconductor layer and a second main electrode provided on the other major surface side. The semiconductor device of the embodiment may be used as, for example, a switching element in a DC-DC converter for which high-speed switching and low ON resistance are required.

Although a Metal-Oxide-Semiconductor Field Effect Transistor (MOSFET) is given as an example of the semiconductor device in the following embodiment, the semiconductor device may be an Insulated Gate Bipolar Transistor (IGBT). In the case of the IGBT, a drain layer 12 of the n⁺ type described below may be replaced with a collector layer of the p⁺ type.

The semiconductor device of the embodiment uses, for example, silicon as the semiconductor material. Alternatively, SiC, for example, may be used.

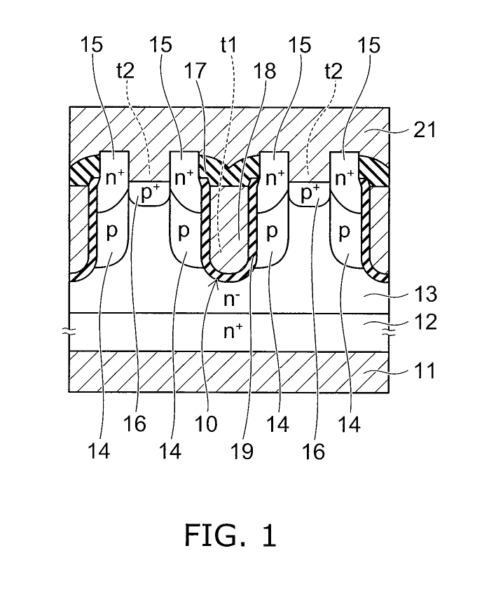

FIG. 1 is a schematic cross-sectional view of a semiconductor device of the embodiment.

The semiconductor device of the embodiment includes a drain layer (or a substrate) 12 of the n⁺ type, a drift layer 13 of the n⁻ type, a base region 14 of the p type, a source region 15 of the n⁺ type, a carrier release region 16 of the p⁺ type, and a trench gate 10. The drain layer 12 and the source region 15 have a higher n-type impurity concentration than the drift layer 13. The carrier release region 16 has a higher p-type impurity concentration than the base region 14.

A drain electrode 11 is provided on the back surface of the drain layer 12 as the first main electrode. The drain layer 12 and the drain electrode 11 are in ohmic contact, and the drain layer 12 is electrically connected to the drain electrode 11.

The drift layer 13 is provided on the drain layer 12. The base region 14 is selectively provided in the drift layer 13. The source region 15 is provided on the base region 14.

A plurality of trench gates 10 are provided in the semiconductor layer including the source region 15, the base region 14, and the drift layer 13. The plurality of trench gates 10 are formed in a planar pattern of stripes extending in the depth direction of the drawing sheet, for example. The trench gate 10 is adjacent to the source region 15 and the base region 14. The trench gate 10 includes a trench t1, a gate insulating film 19, and a gate electrode 18.

The bottom of the trench t1 is located in the drift layer 13. The gate insulating film 19 is provided on the side wall and the bottom of the trench t1. The gate electrode 18 is provided on the inside of the gate insulating film 19 in the trench t1.

The gate electrode 18 is facing to the base region 14 and the source region 15 via the gate insulating film 19. An interlayer film 17 is provided on the gate electrode 18. Part of the gate electrode 18 is led upward from the trench t1 to be connected to a not-shown gate interconnection.

A contact trench t2 is formed between the trench gates 10. The side wall of the contact trench t2 is adjacent to the source region 15. The contact trench t2 is shallower than the gate trench t1 and the source region 15.

The carrier release region (or a contact region) 16 of the p⁺ type with a higher p-type impurity concentration than the base region 14 is formed in a region under the bottom of the contact trench t2 of the drift layer 13. The carrier release region 16 is in contact with the base region 14. Alternatively, the carrier release region 16 may not be in contact with the base region 14.

A source electrode 21 is provided in the contact trench t2 as the second main electrode. The side surface of the source region 15 is in ohmic contact with the source electrode 21 in the contact trench t2. The source electrode 21 is provided also on the surface of the source region 15. Also the surface of the source region 15 is in ohmic contact with the source electrode 21. Therefore, the source region 15 is electrically connected to the source electrode 21.

The carrier release region 16 is in ohmic contact with the source electrode 21 provided in the contact trench t2.

Since the interlayer film 17 made of an insulating material is interposed between the gate electrode 18 and the source electrode 21, the gate electrode 18 and the source electrode 21 are not connected. The drain electrode 11 and the source electrode 21 are made of a metal material. The gate electrode 18 is made of a semiconductor (e.g., polycrystalline silicon) provided with an electrical conductivity by introducing an impurity. Alternatively, a metal may be used as the gate electrode 18.

In the semiconductor device of the embodiment described above, when a desired gate potential is applied to the gate electrode 18 in a state where a relatively high electric potential is applied to the drain electrode 11 and a relatively low electric potential is applied to the source electrode 21, an inversion layer (n channel) is formed in a region near the interface with the gate insulating film 19 of the base region 14. For example, a positive electric potential with respect to the electric potential of the source electrode 21 to which the ground potential or a negative electric potential is applied, is applied to the gate electrode 18. A positive electric potential higher than the gate potential is applied to the drain electrode 11.

Thereby, a current flows between the source electrode 21 and the drain electrode 11 via the source region 15, the n channel, the drift layer 13, and the drain layer 12, leading to the ON state.

If avalanche breakdown occurs at the time of gate OFF, the hole current flows to the source electrode 21 via the carrier release region 16 of the p⁺ type. Thereby, device breakdown can be prevented. The contact trench structure has a structure in which part of the source electrode 21 is buried on the surface side of the semiconductor layer. Therefore, carriers (holes) generated by avalanche breakdown can be rapidly released to the source electrode 21, and a high breakdown withstand capability can be obtained.

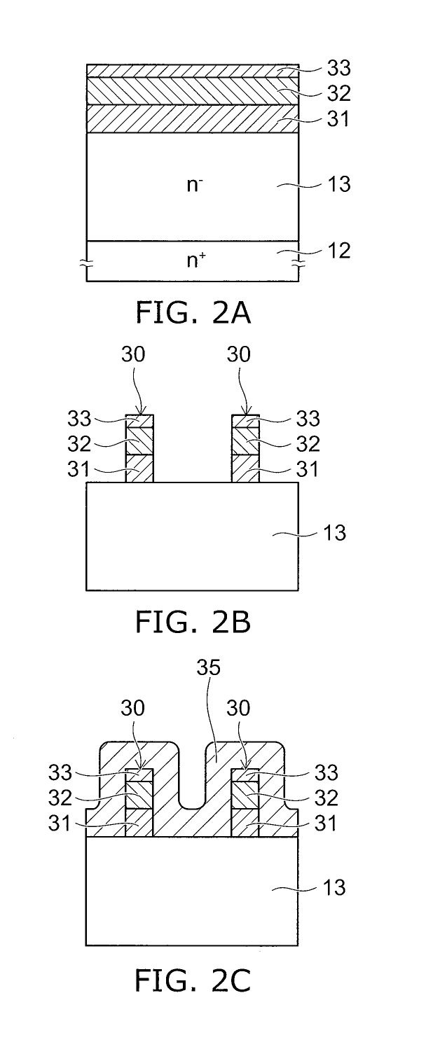

Next, a method for manufacturing a semiconductor device of the embodiment is described with reference to FIG. 2A to FIG. 5C.

As shown in FIG. 2A, the drift layer 13 is formed on the substrate (drain layer) 12. Both of them are silicon layers. The illustration of the substrate 12 is omitted in the process cross-sectional views of FIG. 2B and the subsequent drawings.

Next, a first silicon oxide film (hereinafter, referred to as simply a silicon oxide film) 31 is formed on the drift layer 13. Further, a silicon nitride film 32 is formed on the silicon oxide film 31. Further, a second silicon oxide film (hereinafter, referred to as simply a silicon oxide film) 33 is formed on the silicon nitride film 32.

Next, the silicon oxide film 33, the silicon nitride film 32, and the silicon oxide film 31 are selectively etched by, for example, the reactive ion etching (RIE) method using a not-shown mask. Thereby, as shown in FIG. 2B, a mask layer 30 formed of a stacked structure of the silicon oxide film 31, the silicon nitride film 32, and the silicon oxide film 33 is formed on the drift layer 13. The mask layer 30 is formed in a fin shape extending in the depth direction of the drawing sheet, for example.

Next, a side wall film 35 shown in FIG. 2C is formed on the drift layer 13 so as to cover the top surface and the side wall of the mask layer 30. The side wall film 35 is, for example, a silicon oxide film.

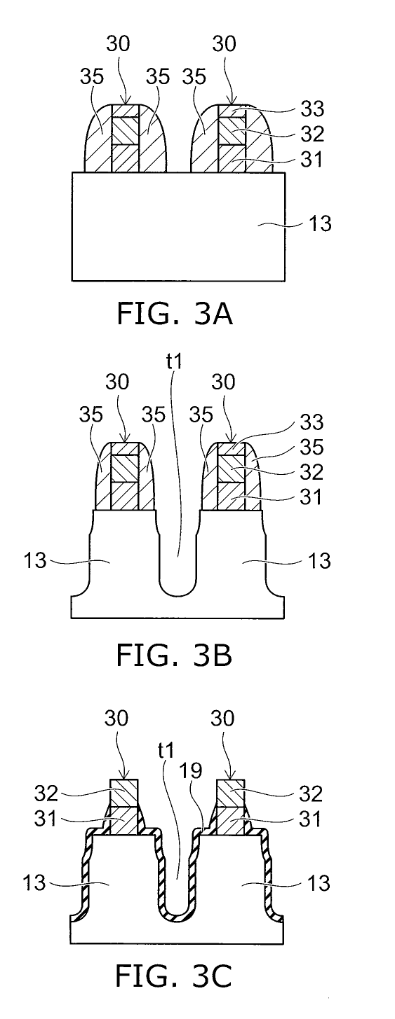

Next, the side wall film 35 is etched by, for example, the RIE method. Thereby, as shown in FIG. 3A, the side wall film 35 is left only on the side wall of the mask layer 30.

Next, the drift layer 13 is etched by, for example, the RIE method using the mask layer 30 and the side wall film 35 formed on the side walls on both sides thereof as a mask. Thereby, the gate trench t1 is formed in the drift layer 13. The gate trench t1 is formed under the surface of the drift layer 13 exposed between the side wall films 35.

After the RIE that has formed the gate trench t1, wet etching is performed in order to remove the reaction products remaining in the gate trench t1. The conditions in the wet etching would cause the silicon nitride film 32 to be undesirably etched. In view of this, in the embodiment, the silicon oxide film 33 is provided on the silicon nitride film 32 to protect the silicon nitride film 32 from the wet etching.

After that, chemical dry etching (CDE), which is an isotropic etching, is performed in order to remove the damage portion due to RIE and improve the shape of the trench bottom (round the trench bottom), and the state shown in FIG. 3B is obtained. Under the conditions in the CDE, since the etching selectivity between silicon and silicon nitride is low, also the silicon nitride film 32 would be undesirably etched. However, in the embodiment, the silicon oxide film 33 provided on the silicon nitride film 32 protects the silicon nitride film 32 in the CDE.

If conditions under which the silicon nitride film 32 is not etched or the etching amount is small are used in the wet etching and the CDE mentioned above, the silicon oxide film 33 provided on the silicon nitride film 32 can be omitted.

Alternatively, conditions such as the film thickness etc. of the silicon nitride film 32 may be controlled in view of the consumption amount of the silicon nitride film 32 in the wet etching and the CDE mentioned above; thereby, the silicon oxide film 33 can be omitted.

After the gate trench t1 is formed, the side wall film 35 is removed by, for example, wet etching. The side wall film 35 is a silicon oxide film, and during the removal thereof, also the silicon oxide film 33 is removed.

Next, the exposed surface of the drift layer 13 including the inner wall of the gate trench t1 is oxidized. Thereby, as shown in FIG. 3C, the gate insulating film (a silicon oxide film) 19 is formed on the inner wall of the gate trench t1. Furthermore, the gate insulating film 19 is formed also on the top surface of the drift layer 13 exposed by the removal of the side wall film 35.

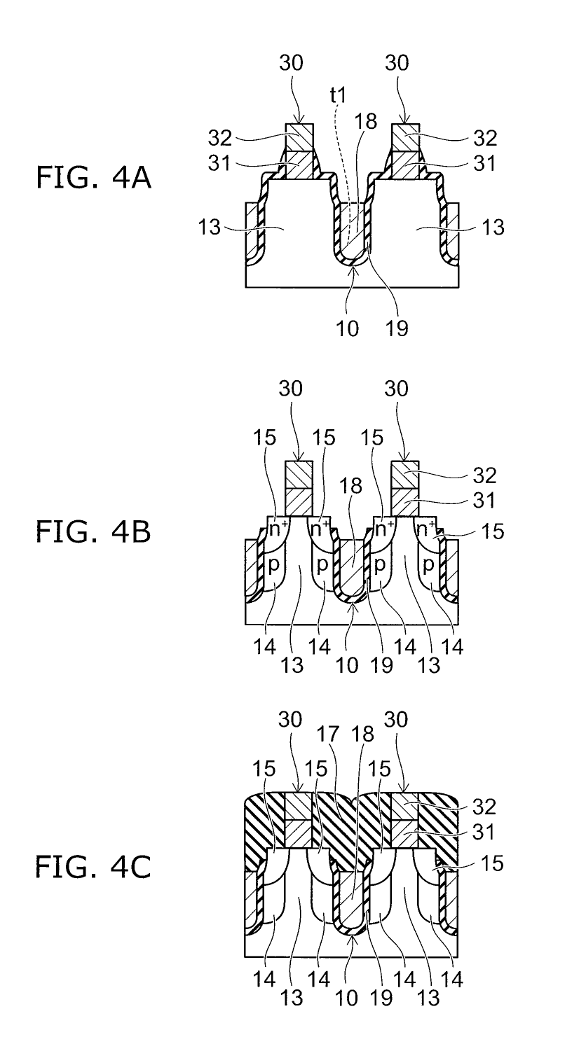

Next, an electrode material such as, for example, polycrystalline silicon is deposited so as to fill the gate trench t1, and then the electrode material is etched back. The electrode material is provided with an electrical conductivity by introducing an impurity. Thereby, as shown in FIG. 4A, the trench gate 10 in which the gate electrode 18 is buried in the gate trench t1 via the gate insulating film 19 is formed.

Next, the gate insulating film 19 formed on the top surface of the drift layer 13 is removed by, for example, the RIE method. Thereby, the surface of the drift layer 13 around the opening end of the gate trench t1 is exposed.

Then, a p-type impurity is implanted into the exposed surface to form the base region 14 shown in FIG. 4B, and further an n-type impurity is implanted to form the source region 15 on the base region 14. At the time of the ion implantation, the mask layer 30 serves as a mask, and the base region 14 and the source region 15 are self-alignedly formed in a region adjacent to the gate trench 10.

Next, as shown in FIG. 4C, the interlayer film 17 is deposited over the entire surface. The interlayer film 17 is a silicon oxide film formed by the chemical vapor deposition (CVD) method, for example. The interlayer film 17 is put in the upper portion of the gate trench t1 on the gate electrode 18, and covers the side wall of the mask layer 30.

After the deposition of the interlayer film 17, the interlayer film 17 is etched back to expose the top surface of the silicon nitride film 32 in the mask layer 30.

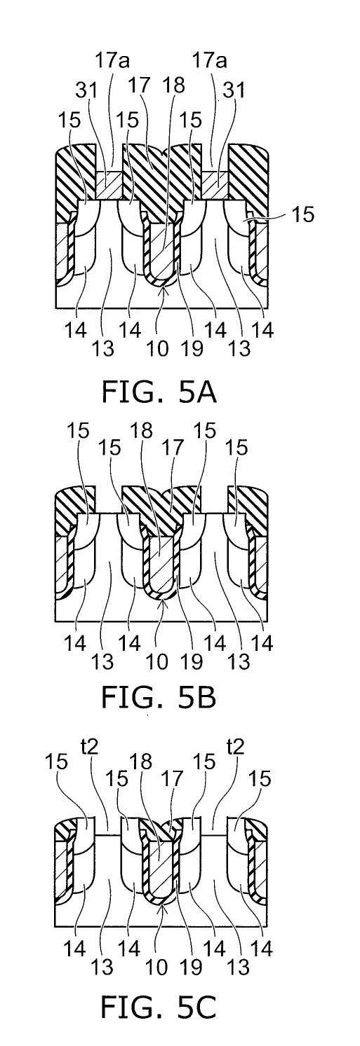

Next, the silicon nitride film 32 is removed by, for example, the CDE method. Only the silicon nitride film 32 in the mask layer 30 is selectively removed. By the removal of the silicon nitride film 32, as shown in FIG. 5A, an opening 17a is formed in the portion on the silicon oxide film 31 of the interlayer film 17. That is, a step is formed between the silicon oxide film 31 and the interlayer film 17 which is thicker than the silicon oxide film 31.

Then, the silicon oxide film 31 and the interlayer film 17, which also is a silicon oxide film, are etched back by, for example, the RIE method. Thereby, both the silicon oxide film 31 and the interlayer film 17 are consumed in the film thickness direction, and the silicon oxide film 31 which is relatively thin is removed (FIG. 5B).

By the removal of the silicon oxide film 31, the surface of the underlying silicon layer is exposed. Then, the silicon layer is etched by, for example, the RIE method using the remaining interlayer film 17 as a mask. Thereby, as shown in FIG. 5C, the contact trench t2 is formed in a portion adjacent to the source regions 15 between the trench gates 10.

Before forming the contact trench t2, most of the top surface of the source region 15 and the gate electrode 18 are covered with the interlayer film 17. That is, the portion where silicon is exposed in the cell region is the surface of the region adjacent to the source region 15. Therefore, the contact trench t2 can be formed by etching silicon selectively in a self-aligned manner without forming a new mask using patterning by lithography. The contact trench t2 is self-alignedly formed with high positional accuracy between the source region 15 and the source region 15 between the trench gates 10.

After that, a p-type impurity is implanted into the region exposed at the bottom of the contact trench t2 of the drift layer 13 by the ion implantation method to form the carrier release region 16 of the p⁺ type shown in FIG. 1. Furthermore, the source electrode 21 and the drain electrode 11 are formed.

According to the embodiment described above, when forming the cell region including the trench gate 10, the source region 15, the base region 14, and the contact trench t2, the patterning process by lithography is performed only in forming the mask layer 30 shown in FIG. 2B. By reducing the number of times of lithography, cost reduction can be achieved.

Furthermore, the source region 15, the base region 14, and the contact trench t2 can be self-alignedly formed with high positional accuracy in a narrow space between the trench gates 10 without being constrained by the optical alignment margin in lithography. By narrowing the pitch between trench gates 10, that is, the cell pitch, the value of current that can be passed per unit area can be increased, and a device with low ON resistance and low cost can be provided.

In the embodiment described above, the lowermost layer in the mask layer 30 is the silicon oxide film 31, and the silicon nitride film 32 is not in contact with the silicon surface of the drift layer 13. Thereby, the contamination and the like of silicon due to the silicon nitride film 32 can be avoided.

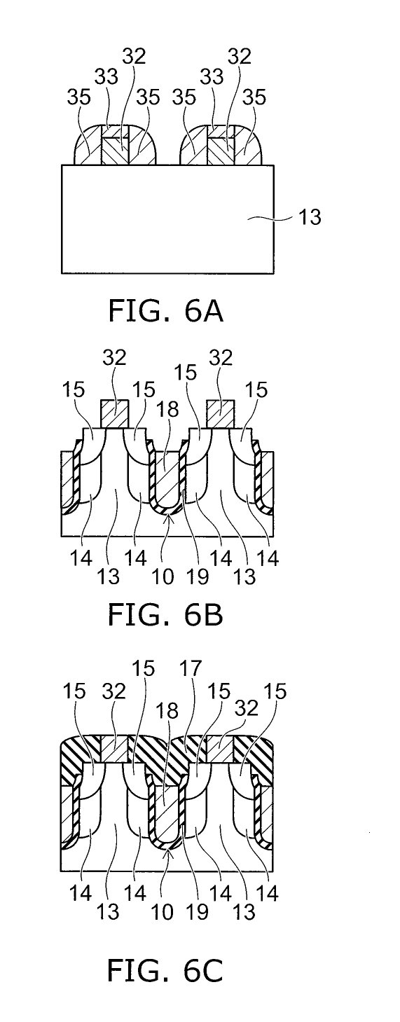

As the mask layer, the silicon nitride film 32 may be provided directly on the drift layer 13 as shown in FIG. 6A without providing the underlying silicon oxide film. Since the silicon oxide film is not formed in the lowermost layer, cost reduction can be achieved.

Also in this case, processes are performed similarly to the embodiment described above to lead to FIG. 6B. FIG. 6B corresponds to FIG. 4B described above. After the interlayer film 17 is formed as shown in FIG. 6C, the silicon nitride film 32 is removed; thereby, the state of FIG. 5B is obtained. Then, the exposed silicon is etched using the interlayer film 17 as a mask; thereby, the contact trench t2 is self-alignedly formed.

Alternatively, in place of the silicon nitride film 32, a semiconductor film such as, for example, polycrystalline silicon may be used. Polycrystalline silicon is a material widely used in semiconductor processes, and allows processes to be performed at low cost using existing equipment and conditions.

Furthermore, as the side wall film 35, other than the silicon oxide film, a silicon nitride film may be used. The side wall film 35 is removed by, for example, wet etching. At this time, when the side wall film 35 is a silicon nitride film, also the silicon nitride film 32 of the mask layer 30 may be undesirably removed. Therefore, a silicon oxide film is preferably used as the side wall film 35 from the viewpoint of the stability of processes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A method for manufacturing a semiconductor device comprising:
forming a mask layer containing silicon nitride on a semiconductor layer containing silicon;
forming a side wall film on a side wall of the mask layer;
etching the semiconductor layer using the mask layer and the side wall film as a mask to form a gate trench in the semiconductor layer;
forming a gate electrode in the gate trench via a gate insulating film;
removing the side wall film and forming a base region and a source region in the semiconductor layer using the mask layer as a mask;
forming an interlayer film covering the semiconductor layer, the gate electrode and the mask layer, and containing silicon oxide;
removing the mask layer selectively; and
forming a contact trench, by using the interlayer film as a mask, in a portion of the semiconductor layer under a portion where the mask layer is removed.

2. The method according to claim 1, wherein the forming the mask layer includes:
forming a silicon oxide film on a surface of the semiconductor layer; and
forming a silicon nitride film on the silicon oxide film.

3. The method according to claim 2, wherein the removing the mask layer selectively includes removing the silicon nitride film and
a step is formed between the silicon oxide film and the interlayer film thicker than the silicon oxide film by the removal of the silicon nitride film.

4. The method according to claim 3, wherein the silicon oxide film is removed by etching the silicon oxide film and the interlayer film in a state of having the step, and the contact trench is formed in a portion of the semiconductor layer under a portion where the silicon oxide film is removed.

5. The method according to claim 2, further comprising forming a second silicon oxide film on the silicon nitride film.

6. The method according to claim 5, further comprising removing reaction products remaining in the gate trench by wet etching in a state where the second silicon oxide film is provided on the silicon nitride film after forming the gate trench.

7. The method according to claim 6, further comprising performing chemical dry etching (CDE) on the gate trench in a state where the second silicon oxide film is provided on the silicon nitride film after the wet etching.

8. The method according to claim 5, wherein also the second silicon oxide film is removed when the side wall film is removed.

9. The method according to claim 1, further comprising forming an electrode in the trench contact and on the source region.

10. The method according to claim 9, further comprising forming a carrier release region with a higher impurity concentration than the base region at a bottom of the trench contact before forming the electrode.

11. The method according to claim 1, wherein the forming the side wall film including
forming the side wall film on the semiconductor layer so as to cover a top surface and a side wall of the mask layer and thereafter performing reactive ion etching (RIE) on the side wall film.

12. The method according to claim 1 wherein
the forming the base region includes using the mask layer as a mask to implant an impurity into a region adjacent to the gate trench of the semiconductor layer and
the forming the source region includes using the mask layer as a mask to implant an impurity of a conductivity type opposite to a conductivity type of the base region into a region on the base region of the semiconductor layer.

13. The method according to claim 3, wherein the forming the step includes:
forming the interlayer film and thereafter etching back the interlayer film to expose a top surface of the silicon nitride film of the mask layer from the interlayer film; and
performing chemical dry etching (CDE) on the silicon nitride film exposed from the interlayer film to remove the silicon nitride film.

14. The method according to claim 1, wherein the contact trench is formed by performing reactive ion etching (RIE) on a surface of the semiconductor layer in a region adjacent to the source region in a state where the interlayer film covers part of a top surface of the source region and the gate electrode.
